(19) United States
(12) Patent Application Publication
(10) Pub. No.: US 2016/0197204 A1
(43) Pub. Date: Jul. 7, 2016

(54) SOLAR CELL AND METHOD FOR MANUFACTURING THE SAME

(71) Applicant: LG ELECTRONICS INC., Seoul (KR)

(72) Inventors: Seungjik LEE, Seoul (KR); Kwangsun JI, Seoul (KR); Yujin LEE, Seoul (KR); Sehwon AHN, Seoul (KR)

(73) Assignee: LG ELECTRONICS INC., Seoul (KR)

(21) Appl. No.: 14/988,513

(22) Filed: Jan. 5, 2016

(30) Foreign Application Priority Data
Jan. 5, 2015 (KR) 10-2015-0000916

(51) Int. Cl. H01L 31/0288; H01L 31/077; H01L 31/0352; H01L 31/18; H01L 31/036

(52) U.S. Cl. CPC H01L 31/0288; H01L 31/18; H01L 31/036; H01L 31/035281; H01L 31/077

(57) ABSTRACT

A solar cell and a method for manufacturing the same are discussed. The solar cell includes a crystalline semiconductor substrate containing impurities of a first conductive type, a tunnel layer positioned on the crystalline semiconductor substrate, a semiconductor layer which is formed on the tunnel layer, has a crystallinity less than the crystalline semiconductor substrate, and includes a first doped region of a second conductive type opposite the first conductive type and a second doped region containing impurities of the first conductive type at a higher concentration than that of the crystalline semiconductor substrate, a first electrode connected to the first doped region, and a second electrode connected to the second doped region.

### CROSS-REFERENCE TO RELATED APPLICATION

This application claims priority to and the benefit of Korean Patent Application No. 10-2015-0000916 filed in the Korean Intellectual Property Office on Jan. 5, 2015, the entire contents of which are incorporated herein by reference.

### BACKGROUND OF THE INVENTION

1. Field of the Invention

Embodiments of the invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Hence, solar cells for generating electric energy from solar energy have been particularly spotlighted.

A silicon solar cell generally includes a semiconductor substrate and an emitter region, which are formed of semiconductors of different conductive types, for example, a p-type and an n-type, and electrodes respectively connected to the semiconductor substrate and the emitter region. A p-n junction is formed at an interface between the semiconductor substrate and the emitter region.

When light is incident on the solar cell, a plurality of electron-hole pairs are generated in the semiconductors. The electron-hole pairs are separated into electrons and holes by a photovoltaic effect. The electrons move to the n-type semiconductor, for example, the emitter region, and the holes move to the p-type semiconductor, for example, the semiconductor substrate. Then, the electrons and the holes are collected by the electrodes electrically connected to the emitter region and the semiconductor substrate. The solar cell obtains electric power by connecting the electrodes using electric wires.

However, in this instance, the electrodes are positioned on the emitter region formed on the surface (i.e., an incident surface) of the semiconductor substrate, on which light is incident, as well as the surface of the semiconductor substrate, on which light is not incident. Therefore, an incident area of light decreases, and the efficiency of the solar cell is reduced.

Thus, a back contact solar cell, in which all of the electrodes collecting electrons and holes are positioned on a back surface of the semiconductor substrate, has been developed, so as to increase the incident area of light.

### SUMMARY OF THE INVENTION

In one aspect, there is provided a solar cell including a crystalline semiconductor substrate containing impurities of a first conductive type, a tunnel layer positioned on the crystalline semiconductor substrate, a semiconductor layer formed on the tunnel layer, the semiconductor layer having a crystallinity less than a crystallinity of the crystalline semiconductor substrate, the semiconductor layer including a first doped region of a second conductive type opposite the first conductive type and a second doped region containing impurities of the first conductive type at a higher concentration than that of the crystalline semiconductor substrate, a first electrode connected to the first doped region, and a second electrode connected to the second doped region, wherein at least one of the first doped region or the second doped region includes a first portion having a first specific resistance and a second portion having a second specific resistance, the first specific resistance being larger than the second specific resistance.

The first specific resistance of the first portion may be 8.75×10⁻⁴ to 1.0×10⁻² Ωcm, and The second specific resistance of the second portion is 1.75×10⁻³ to 5.0×10⁻³ Ωcm. Alternatively, the first specific resistance of the first portion may be 8.7×10⁻³ to 1.0×10⁻² Ωcm, and the second specific resistance of the second portion may be 2.5×10⁻³ to 5.0×10⁻³ Ωcm.

A crystallinity of the first portion may be less than a crystallinity of the crystalline semiconductor substrate and a crystallinity of the second portion. The crystallinity of the first portion may be equal to or less than about 40 vol %, and the crystallinity of the second portion may exceed about 40 vol %. The crystallinity of the second portion may be about 70 vol % to about 90 vol %.

The first portion may be in the plural, and the second portion may be positioned between the plurality of first portions. The second portion may be positioned on the first electrode or the second electrode.

Each of the first and second portions may have a dot shape, and the second portion may be positioned inside the first portion.

The solar cell may further include a third doped region on a front surface of the crystalline semiconductor substrate and an intrinsic semiconductor layer formed between the first doped region and the second doped region and positioned on the tunnel layer, on which the first doped region and the second doped region are not formed.

In another aspect, there is provided a method for manufacturing a solar cell including preparing a crystalline semiconductor substrate containing impurities of a first conductive type, forming a tunnel layer on the crystalline semiconductor substrate, forming an intrinsic semiconductor layer on the tunnel layer, diffusing impurities of a second conductive type opposite the first conductive type into the intrinsic semiconductor layer to form a first doped region having a crystallinity less than a crystallinity of the crystalline semiconductor substrate, and diffusing impurities of the first conductive type into the intrinsic semiconductor layer to form a second doped region having a crystallinity less than the crystallinity of the crystalline semiconductor substrate, wherein the forming of the first doped region or the second doped region includes forming an impurity layer containing impurities of the second conductive type or impurities of the first conductive type at the intrinsic semiconductor layer, irradiating a laser onto the impurity layer, and diffusing the impurity layer.

The diffused impurity layer may form the first doped region or the second doped region through thermal processing.

The crystallinity of the first doped region or the second doped region may be about 40 vol % to about 90 vol %.

At least one of the first doped region or the second doped region may include a first portion and a second portion each having a different specific resistance depending on an amount of laser irradiation.

At least one of the first doped region or the second doped region may include a first portion and a second portion each having a different crystallinity depending on an amount of laser irradiation.

In yet another aspect, there is provided a method for manufacturing a solar cell including doping a second impurity layer of a second conductive type opposite a first conductive type on a back surface of a semiconductor substrate containing impurities of the first conductive type to form a first doped region, doping a first impurity layer containing impurities of the first conductive type on the back surface of the semiconductor substrate to form a second doped region, and additionally doping the first impurity layer or the second impurity layer on the first doped region or the second doped region to form a first portion or a second portion each having a different impurity doping concentration. An impurity doping concentration of the first portion may be lower than an impurity doping concentration of the second portion. The first portion or the second portion may be formed through laser irradiation.

According to the above aspects, a front surface field region having a predetermined thickness is formed on the front surface of the semiconductor substrate through the laser irradiation, and then an emitter region and a back surface field region are formed at the back surface of the semiconductor substrate by diffusing impurities of the first and second conductive types. Thus, a separate etching process for etching the front surface field region is not necessary. Hence, the manufacturing process of the solar cell can be simplified, and the manufacturing cost of the solar cell can be reduced. As a result, the efficiency of the solar cell can be improved.

Furthermore, because a back surface field region has a shape of oval or polygon (for example, rectangular) dot, an area of the intrinsic semiconductor layer can be maximized while satisfactorily maintaining a contact strength and a contact resistance. Hence, a passivation function can further increase.

Furthermore, the laser is selectively irradiated onto impurities of the first or second conductive type to form the emitter region or the back surface field region each having a heavily doped region or a lightly doped region each having a different impurity doping concentration. Hence, the passivation function can further increase, and the efficiency of the solar cell can further increase.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial perspective view of a solar cell according to an example embodiment of the invention;

FIG. 2 is a schematic cross-sectional view taken along line II-II of FIG. 1;

FIGS. 3A and 3B illustrate examples of a pattern of an emitter region and a back surface field region positioned on a back surface of a solar cell according to an example embodiment of the invention;

FIGS. 4A to 4K sequentially illustrate a method for manufacturing a solar cell according to an example embodiment of the invention;

FIG. 5 illustrates in detail a structure of a back surface field region;

FIG. 6 is a partial perspective view of a solar cell according to another example embodiment of the invention; and

FIG. 7 illustrates a method for manufacturing a solar cell according to another example embodiment of the invention.

### DETAILED DESCRIPTION OF THE EMBODIMENTS

Reference will now be made in detail to embodiments of the invention, examples of which are illustrated in the accompanying drawings. This invention may, however, be embodied in many different forms and should not be construed as limited to the embodiments set forth herein. Wherever possible, the same reference numbers will be used throughout the drawings to refer to the same or like parts. It should be noted that a detailed description of the known arts will be omitted if it is determined that the detailed description of the known arts can obscure the embodiments of the invention.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on other element, it may be on the entire surface of the other element and may not be on a portion of an edge of the other element.

In the following description, “front surface” may be one surface of a semiconductor substrate, on which light is directly incident, and “back surface” may be a surface opposite the one surface of the semiconductor substrate, on which light is not directly incident or reflective light may be incident.

Further, in the following description, the fact that lengths or widths of different components are the same as each other means that they are the same as each other within a margin of error of 10%.

Exemplary embodiments of the invention are described in detail below with reference to 1 to 7.

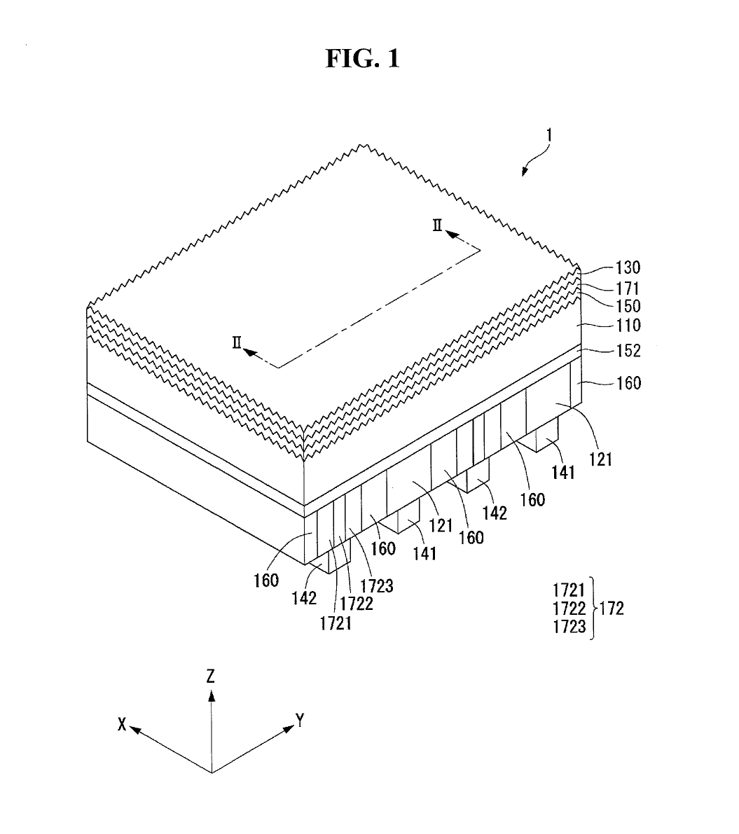

FIGS. 1 to 3B illustrate a solar cell according to an example embodiment of the invention.

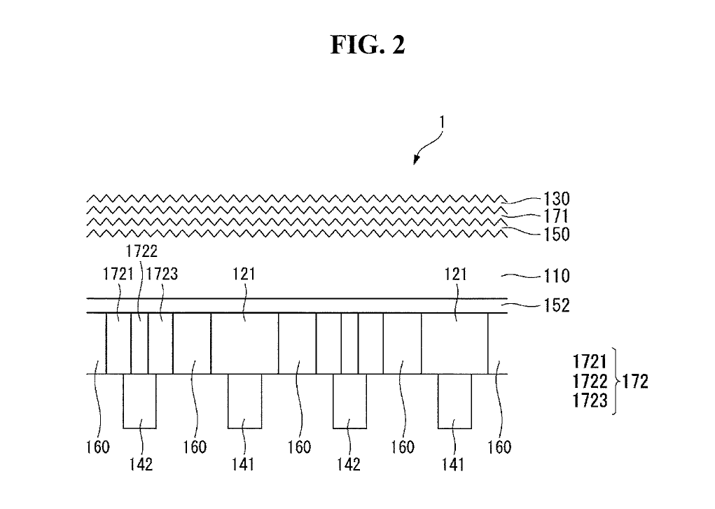

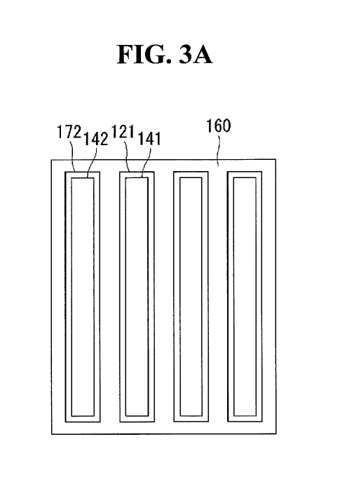

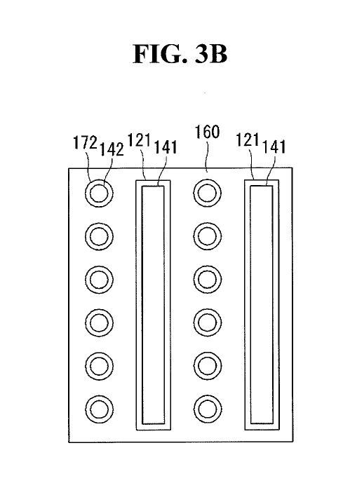

More specifically, FIG. 1 is a partial perspective view of a solar cell according to an example embodiment of the invention. FIG. 2 is a schematic cross-sectional view taken along line II-II of FIG. 1. FIGS. 3A and 3B illustrate examples of a pattern of an emitter region and a back surface field region positioned on a back surface of a solar cell according to an example embodiment of the invention.

As shown in FIGS. 1 and 2, a solar cell 1 according to the embodiment of the invention may include an anti-reflection layer 130, a front surface field region 171, a front tunnel layer 150, a semiconductor substrate 110, a back tunnel layer 152, a plurality of emitter regions 121, a plurality of back surface field regions 172, an intrinsic semiconductor layer 160, a plurality of first electrodes 141, and a plurality of second electrodes 142.

In the embodiment of the invention, the anti-reflection layer 130, the intrinsic semiconductor layer 160, the front tunnel layer 150, and the back tunnel layer 152 may be omitted, if desired or necessary. However, when the solar cell 1 includes the anti-reflection layer 130, the intrinsic semiconductor layer 160, the front tunnel layer 150, and the back tunnel layer 152, efficiency of the solar cell 1 may be further improved. Thus, the embodiment of the invention is described using the solar cell 1 including the anti-reflection layer 130, the intrinsic semiconductor layer 160, the front tunnel layer 150, and the back tunnel layer 152, as an example.

The semiconductor substrate 110 may be formed of at least one of single crystal silicon and polycrystalline silicon containing impurities of a first conductive type. For example, the semiconductor substrate 110 may be formed of a single crystal silicon wafer.

In the embodiment disclosed herein, the first conductive type may be one of an n-type and a p-type.

When the semiconductor substrate 110 is of the p-type, the semiconductor substrate 110 may be doped with impurities of a group III element, such as boron (B), gallium (Ga), and indium (In). Alternatively, when the semiconductor substrate 110 is of the n-type, the semiconductor substrate 110 may be doped with impurities of a group V element, such as phosphorus (P), arsenic (As), and antimony (Sb).

In the following description, the embodiment of the invention is described using an example where the first conductive type is the n-type.

A front surface of the semiconductor substrate 110 may be an uneven surface having a plurality of uneven portions or having uneven characteristics. Thus, emitter region 121 positioned on the front surface of the semiconductor substrate 110 may have an uneven surface.

Hence, an amount of light reflected from the front surface of the semiconductor substrate 110 may decrease, and an amount of light incident inside the semiconductor substrate 110 may increase.

The anti-reflection layer 130 is positioned on the front surface of the semiconductor substrate 110 and may be formed of at least one of aluminum oxide (AlOx), silicon nitride (SiNx), silicon oxide (SiOx), and silicon oxynitride (SiOxNy), thereby minimizing the reflection of light incident on the front surface of the semiconductor substrate 110 from the outside. As shown in FIGS. 1 and 2, the anti-reflection layer 130 may have a single layer. Alternatively, the anti-reflection layer 130 may have a plurality of layers.

The front surface field region 171 is positioned on the front tunnel layer 150 and may be a region which is more heavily doped than the semiconductor substrate 110 with impurities of the same conductive type as the semiconductor substrate 110. For example, if the semiconductor substrate 110 is doped with n-type impurities, the front surface field region 171 may be an n⁺-type region.

A potential barrier is formed by a difference between impurity concentrations of the semiconductor substrate 110 and the front surface field region 171 and thus prevents carriers (for example, holes) from moving to the front surface of the semiconductor substrate 110. Thus, the front surface field region 171 may obtain a field effect, which causes holes moving to the front surface of the semiconductor substrate 110 to return to a back surface of the semiconductor substrate 110 by the potential barrier. Hence, the front surface field region 171 can increase an amount of carriers output to an external device and reduce an amount of carriers lost by a recombination and/or a disappearance of electrons and holes at and around the front surface of the semiconductor substrate 110.

The front tunnel layer 150 and the back tunnel layer 152 are respectively positioned on the entire front surface and the entire back surface of the semiconductor substrate 110 while directly contacting them, respectively. The front tunnel layer 150 and the back tunnel layer 152 may include a dielectric material. Thus, as shown in FIGS. 1 and 2, the front tunnel layer 150 and the back tunnel layer 152 may directly contact the front surface and the back surface of the semiconductor substrate 110 formed of single crystal silicon and may pass carriers produced in the semiconductor substrate 110.

The front tunnel layer 150 and the back tunnel layer 152 may pass carriers produced in the semiconductor substrate 110 and may perform a passivation function with respect to the front surface and the back surface of the semiconductor substrate 110.

The front tunnel layer 150 and the back tunnel layer 152 may be formed of a dielectric material including silicon carbide (SiCx) or silicon oxide (SiOx) having strong durability at a high temperature equal to or higher than 600° C. In addition, the front tunnel layer 150 and the back tunnel layer 152 may be formed of silicon nitride (SiNx), hydrogenated SiNx, aluminum oxide (AlOx), silicon oxynitride (SiON), or hydrogenated SiON. Each of the front tunnel layer 150 and the back tunnel layer 152 may have a thickness of 0.5 nm to 5 nm.

When the thickness of the front tunnel layer 150 and the back tunnel layer 152 is equal to or greater than 0.5 nm, the passivation function of the front tunnel layer 150 and the back tunnel layer 152 with respect to the surface of the semiconductor substrate 110 may be secured. When the thickness of the front tunnel layer 150 and the back tunnel layer 152 is equal to or less than 5 nm, a tunneling effect for moving carriers to the emitter region 121 through the front tunnel layer 150 and the back tunnel layer 152 may be secured.

When the thickness of the front tunnel layer 150 and the back tunnel layer 152 exceeds 5 nm, an amount of carriers moving to the first electrodes 141 through the front tunnel layer 150 and the back tunnel layer 152 may decrease because of a reduction in the tunneling effect. The embodiment of the invention may further improve a short circuit current of the solar cell 1 through the passivation function and the tunneling effect of the front tunnel layer 150 and the back tunnel layer 152.

The plurality of emitter regions 121 directly contact a portion of a back surface of the back tunnel layer 152 and each extend in a first direction x. The emitter regions 121 may be formed of a polycrystalline silicon material of a second conductive type opposite the first conductive type. The emitter region 121 may form a p-n junction along with the semiconductor substrate 110 with the back tunnel layer 152 interposed therebetween. In the embodiment of the invention, the emitter region 121 may be formed as an amorphous silicon layer or a polycrystalline silicon layer.

Because each emitter region 121 forms the p-n junction along with the semiconductor substrate 110, the emitter region 121 may be of the p-type. However, if the semiconductor substrate 110 is of the p-type unlike the embodiment described above, the emitter region 121 may be of the n-type. In this instance, separated electrons may move to the plurality of emitter regions 121, and separated holes may move to the plurality of back surface field regions 172.

Returning to the embodiment of the invention, when the emitter regions 121 are of the p-type, the emitter regions 121 may be doped with impurities of a group III element, such as B, Ga, and In. On the contrary, if the emitter regions 121 are of the n-type, the emitter regions 121 may be doped with impurities of a group V element, such as P, As, and Sb.

The emitter regions 121 may be formed by depositing the intrinsic semiconductor layer 160 on the back surface of the back tunnel layer 152 and then diffusing impurities of the second conductive type into the intrinsic semiconductor layer 160.

The plurality of back surface field regions 172 may be positioned at the back surface of the back tunnel layer 152, on which the plurality of emitter regions 121 are not positioned, and may directly contact the back surface of the back tunnel layer 152. The plurality of back surface field regions 172 may extend in the same first direction x as the plurality of emitter regions 121. In the embodiment of the invention, the back surface field region 172 may be formed.

as an amorphous silicon layer or a polycrystalline silicon layer in the same manner as the emitter region 121.

The back surface field regions 172 may be formed of a polycrystalline silicon material doped with impurities of the first conductive type at a higher concentration than that of the semiconductor substrate 110. For example, when the semiconductor substrate 110 is doped with n-type impurities, the back surface field region 172 may be an n⁺-type region.

A potential barrier is formed by a difference between impurity concentrations of the semiconductor substrate 110 and the back surface field regions 172. Thus, the back surface field regions 172 can prevent or reduce holes from moving to the back surface field regions 172 used as a moving path of electrons through the potential barrier and can make it easier for carriers (for example, electrons) to move to the back surface field regions 172.

Further, the back surface field regions 172 can reduce an amount of carriers lost by a recombination and/or a disappearance of electrons and holes at and around the back surface field regions 172 or at and around the first and second electrodes 141 and 142 and can accelerate a movement of electrons, thereby increasing an amount of electrons moving to the back surface field regions 172.

The back surface field regions 172 may be formed by depositing the intrinsic semiconductor layer 160 on the back surface of the back tunnel layer 152, recrystallizing the intrinsic semiconductor layer 160 through laser irradiation, and diffusing impurities of the second conductive type into the recrystallized intrinsic semiconductor layer 160.

The back surface field region 172 thus formed may include a first portion 1721 having a first impurity doping concentration, a second portion 1722 having a second impurity doping concentration, and a third portion 1723 having a third impurity doping concentration depending on an amount of the laser irradiation. In this instance, the second portion 1722 may be positioned between the first portion 1721 and the third portion 1723.

In the embodiment of the invention, a sheet resistance of the second portion 1722 may be 25 Ohm/sq at most, and a specific resistance of the second portion 1722 may be 8.75×10⁻⁴ to 1.0×10⁻² Ωcm. Sheet resistances of the first portion 1721 and the third portion 1723 may be 50 Ohm/sq at most, and specific resistances of the first portion 1721 and the third portion 1723 may be the same as each other and may be 1.75×10⁻³ to 5.0×10⁻³ Ωcm. The sheet resistance of the first portion 1721 may be larger or smaller than the sheet resistance of the third portion 1723. Each of the first to third portions 1721, 1722, and 1723 may have a predetermined impurity doping concentration within the fixed range or have an impurity doping concentration which continuously or discontinuously changes within the fixed range.

Hence, the second impurity doping concentration of the second portion 1722 may be higher than the first impurity doping concentration of the first portion 1721 and the third impurity doping concentration of the third portion 1723. The first impurity doping concentration of the first portion 1721 may be equal to or different from the third impurity doping concentration of the third portion 1723. Further, the first impurity doping concentration of the first portion 1721 may be higher or lower than the third impurity doping concentration of the third portion 1723.

As shown in FIG. 3A, the back surface field region 172 may have a stripe shape extending in a forward direction (X). Alternatively, as shown in FIG. 3B, the back surface field region 172 may have a shape of circular dot (for example, island). In alternative examples, the back surface field region 172 may have a shape of oval or polygon (for example, rectangular) dot. The back surface field region 172 may directly adjoin the second electrode 142.

The intrinsic semiconductor layer 160 may be formed in a space between the emitter region 121 and the back surface field region 172 on the back surface of the back tunnel layer 152 while directly contacting the back surface of the back tunnel layer 152. The intrinsic semiconductor layer 160 may be formed of intrinsic polycrystalline silicon, which is not doped with impurities of the first conductive type or impurities of the second conductive type, unlike the emitter region 121 and the back surface field region 172.

As described above, the intrinsic semiconductor layer 160 may be formed in the space between the emitter region 121 and the back surface field region 172 on the back surface of the back tunnel layer 152. In this instance, as shown in FIGS. 1 and 2, both sides of the intrinsic semiconductor layer 160 may directly contact the side of the emitter region 121 and the side of the back surface field region 172, respectively.

The intrinsic semiconductor layer 160 may be formed on the back surface of the semiconductor substrate 110 using a deposition process, such as a chemical vapor deposition (CVD) method and a plasma enhanced chemical vapor deposition (PECVD) method.

The plurality of first electrodes 141 may be respectively positioned on the plurality of emitter regions 121. The first electrode 141 may extend along the emitter region 121 and may be electrically and physically connected to the emitter region 121. Hence, the first electrode 141 may collect carriers (for example, holes) moving to the corresponding emitter region 121.

The plurality of second electrodes 142 may be respectively positioned on the plurality of back surface field regions 172. The second electrode 142 may extend along the back surface field region 172 and may be electrically and physically connected to the back surface field region 172. Hence, the second electrode 142 may collect carriers (for example, electrons) moving to the corresponding back surface field region 172.

The plurality of second electrodes 142 may have the same shape as the plurality of back surface field regions 172 as shown in FIGS. 3A and 3B.

As shown in FIG. 3A, when the back surface field region 172 has the stripe shape, the second electrode 142 on the back surface field region 172 may have a stripe shape extending along the back surface field region 172.

As shown in FIG. 3B, when the back surface field region 172 has the shape of circular, oval, or polygon dot, the second electrode 142 may have a shape of circular, oval, or polygon dot because the second electrode 142 is connected to the back surface field region 172.

Hence, the second portion 1722 of the back surface field region 172 may be formed inside the first portion 1721 and the third portion 1723. Namely, the second portion 1722 may be surrounded by the first portion 1721 and the third portion 1723.

Because the second electrode 142 is positioned inside a formation location of the back surface field region 172, a width of the second electrode 142 may be equal to or less than a width of the back surface field region 172.

In this instance, because a formation area of the back surface field region 172 having the dot shape is less than a formation area of the back surface field region 172 having the stripe shape, a collection efficiency of the second electrodes 142 of the dot shape collecting carriers moving to the back surface of the semiconductor substrate 110 may decrease.

Accordingly, it may be preferable, but not required, that a distance between centers of the two adjacent back surface field regions 172 having the dot shape is less than a distance between centers of the two adjacent back surface field regions 172 having the stripe shape, so as to improve the carrier collection efficiency of the second electrodes 142 having the dot shape. As the distance between the centers of the adjacent back surface field regions 172 decreases, an amount of carriers moving to the back surface field regions 172 may increase through a reduction in a moving distance of carriers.

Because the plurality of back surface field regions 172 of the dot shape are partially positioned at the back surface of the semiconductor substrate 110, an area of the intrinsic semiconductor layer 160 may be maximized. Hence, the passivation function may further increase. Namely, an amount of carriers collected by the second electrode 142 may increase by improving the conductivity of the back surface field region 172 adjoining the second electrode 142 while reducing a contact resistance between the back surface field region 172 and the second electrode 142. As a result, the efficiency of the solar cell 1 may be improved.

Because the back surface field region 172 has the shape of circle, oval, or polygon dot, the area of the intrinsic semiconductor layer 160 may be maximized while satisfactorily maintaining a contact strength and the contact resistance. Hence, the passivation function may further increase.

The plurality of first and second electrodes 141 and 142 may be formed of at least one conductive material selected from the group consisting of nickel (Ni), copper (Cu), silver (Ag), aluminum (Al), tin (Sn), zinc (Zn), indium (In), titanium (Ti), gold (Au), and a combination thereof. Other materials may be used.

The solar cell 1 according to the embodiment of the invention is a back contact solar cell, in which all of the first and second electrodes 141 and 142 are positioned on the back surface of the semiconductor substrate 110, on which light is not incident. An operation of the back contact solar cell 1 having the above-described structure is described below.

When light irradiated onto the solar cell 1 is incident on the semiconductor substrate 110 through the anti-reflection layer 130, the front surface field region 171, and the front tunnel layer 150, a plurality of electron-hole pairs are generated in the semiconductor substrate 110 by light energy produced based on the incident light. In this instance, because the front surface of the semiconductor substrate 110 is the textured surface, a light reflectance at the front surface of the semiconductor substrate 110 is reduced. Further, because both incident and reflective operations are performed at the textured surface of the semiconductor substrate 110, a light absorptance increases. Hence, the efficiency of the solar cell 1 is improved. In addition, because a reflection loss of light incident on the semiconductor substrate 110 is reduced by the anti-reflection layer 130, an amount of light incident on the semiconductor substrate 110 may further increase.

The electron-hole pairs are separated into electrons and holes due to the p-n junction between the semiconductor substrate 110 and the emitter regions 121. Then, the separated electrons move to the n-type emitter regions 121 and then are collected by the first electrodes 141, and the separated holes move to the p-type back surface field regions 172 and then are collected by the second electrodes 142.

When the first and second electrodes 141 and 142 are connected to each other using electric wires, current flows therein to thereby enable use of the current for electric power. In this instance, because the front surface field region 171 and the back surface field regions 172 are respectively positioned at the front surface and the back surface of the semiconductor substrate 110, a recombination and/or a disappearance of electrons and holes at and around the surface of the semiconductor substrate 110 may be prevented or reduced. Hence, the efficiency of the solar cell 1 may be improved.

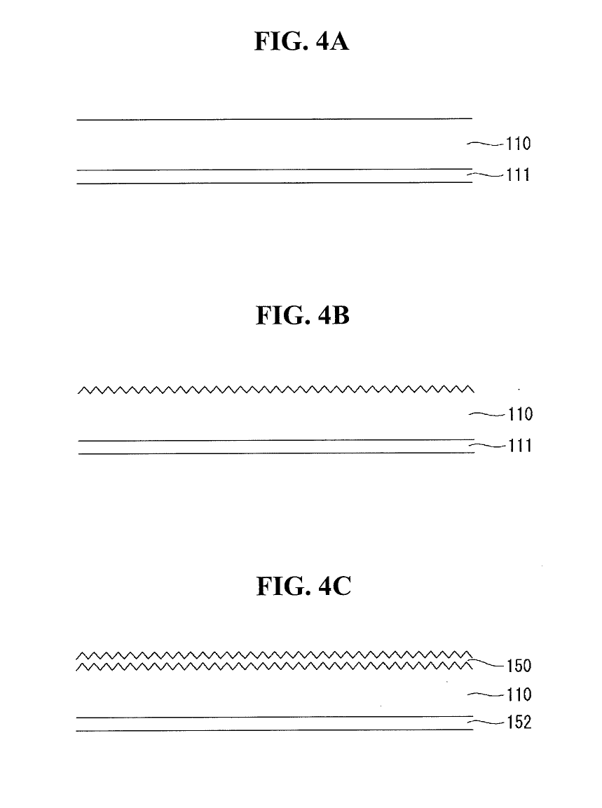

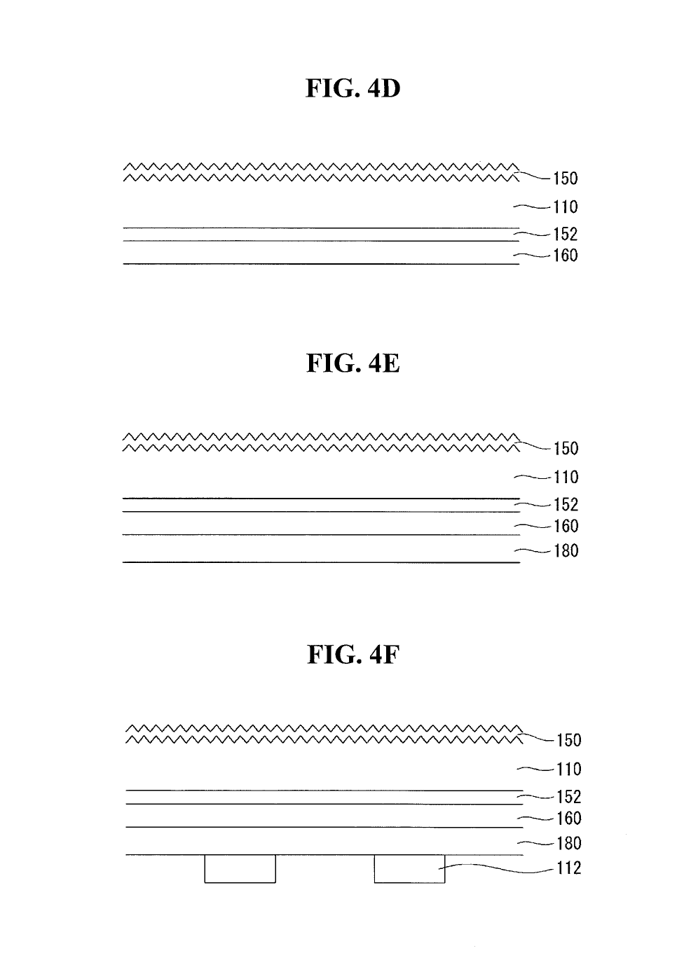

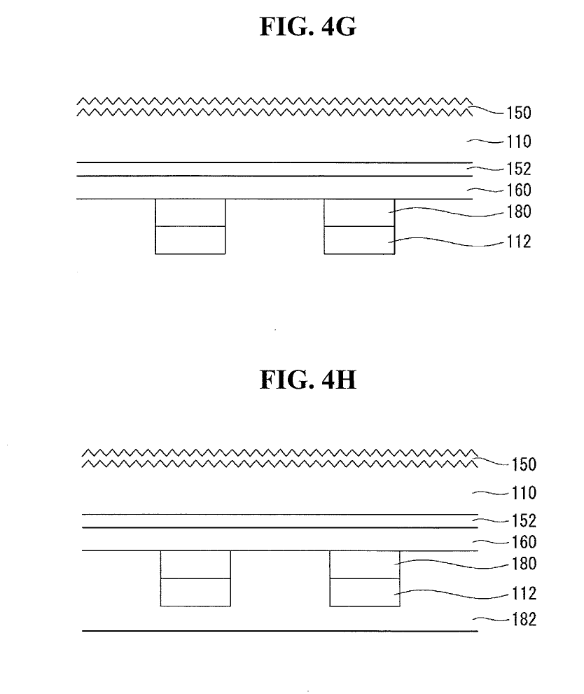

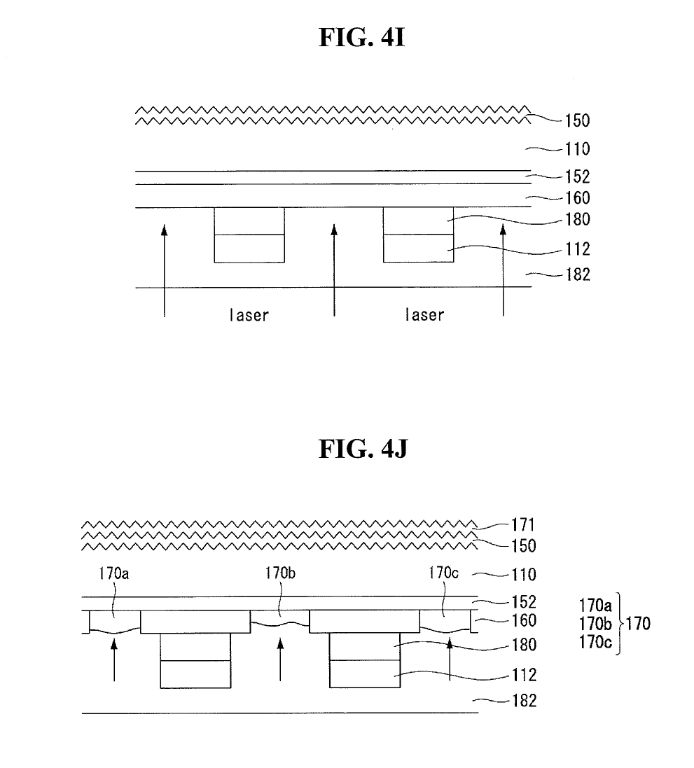

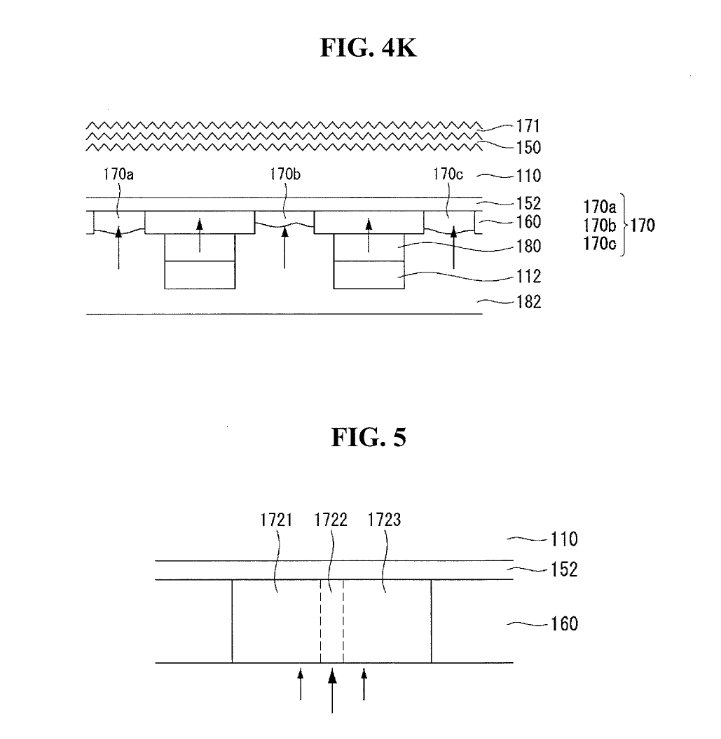

Hereinafter, a method for manufacturing the solar cell 1 according to the embodiment of the invention is described with reference to FIGS. 4A to 4K.

As shown in FIG. 4A, the semiconductor substrate 110 formed of n-type single crystal silicon may be prepared, and an etch stop layer 111 formed of silicon oxide (SiOx), etc., may be stacked on one surface, for example, the back surface of the semiconductor substrate 110.

Next, as shown in FIG. 4B, the other surface, for example, the front surface of the semiconductor substrate 110, on which the etch stop layer 111 is not formed, is etched using the etch stop layer 111 as a mask to form a textured surface having a plurality of uneven portions on the front surface of the semiconductor substrate 110, on which light is incident. Then, the etch stop layer 111 may be removed. When the semiconductor substrate 110 is formed of single crystal silicon, the surface of the semiconductor substrate 110 may be textured using an alkaline solution, such as KOH, NaOH, and TMAH. On the other hand, if the semiconductor substrate 110 is formed of polycrystalline silicon, the surface of the semiconductor substrate 110 may be textured using an acid solution, such as HF and HNO₃.

Next, as shown in FIG. 4C, the front tunnel layer 150 and the back tunnel layer 152 may be respectively formed on the front surface and the back surface of the n-type semiconductor substrate 110. The front tunnel layer 150 and the back tunnel layer 152 may pass carriers produced in the semiconductor substrate 110 and may perform a passivation function with respect to the front surface and the back surface of the semiconductor substrate 110.

The front tunnel layer 150 and the back tunnel layer 152 may be formed of a dielectric material including silicon carbide (SiCx) or silicon oxide (SiOx) having strong durability at a high temperature equal to or higher than 600° C.

Next, as shown in FIG. 4D, the intrinsic semiconductor layer 160 may be deposited on the back surface of the back tunnel layer 152.

The intrinsic semiconductor layer 160 may be formed on the back surface of the semiconductor substrate 110 through the deposition process, such as a chemical vapor deposition (CVD) method and a plasma enhanced chemical vapor deposition (PECVD) method.

Next, as shown in FIG. 4E, a first dopant layer 180 containing impurities of a second conductive type opposite a first conductive type of the semiconductor substrate 110 may be formed on the intrinsic semiconductor layer 160.

Because the semiconductor substrate 110 is of the n-type in the embodiment of the invention, the first dopant layer 180 containing impurities of the p-type (i.e., impurities of a group III element) may be formed. In this instance, the first dopant layer 180 may be formed through the deposition process, such as the CVD method and the PECVD method.

Next, as shown in FIG. 4F, an interlayer dielectric 112 may be deposited on the first dopant layer 180.

The interlayer dielectric 112 may be deposited with undoped silicate glass (USG) at a thickness of about 5 μm and thus may be formed as an oxide layer.

Next, as shown in FIG. 4G, a portion of the first dopant layer 180, on which the interlayer dielectric 112 is not formed, may be etched using the interlayer dielectric 112 as a mask to expose a portion of the intrinsic semiconductor layer 160.

Next, as shown in FIG. 4H, a second dopant layer 182 containing impurities of the same first conductive type as the semiconductor substrate 110 may be formed on the exposed portion of the intrinsic semiconductor layer 160 and the interlayer dielectric 112.

Because the semiconductor substrate 110 is of the n-type in the embodiment of the invention, the second dopant layer 182 containing impurities of the n-type (i.e., impurities of a group V element) may be formed. In this instance, the second dopant layer 182 may be formed through the same process as the first dopant layer 180.

Next, an anti-diffusion layer may be additionally formed on an entire back surface of the second dopant layer 182. The anti-diffusion layer may prevent the diffusion of the second dopant layer 182 and may be formed of an insulating material, for example, polymer.

Next, as shown in FIG. 4I, the intrinsic semiconductor layer 160 may be recrystallized using a laser. As shown in FIG. 4J, impurities of the second conductive type may be diffused into the recrystallized intrinsic semiconductor layer 160 to form an impurity region 170 at the back surface of the semiconductor substrate 110, i.e., a portion of the intrinsic semiconductor layer 160.

And at the same time, impurities of the second conductive type (for example, the n-type) may be diffused into the front surface of the semiconductor substrate 110, i.e., the entire surface of the front tunnel layer 150 to form the front surface field region 171.

The impurity region 170 may include first to third impurity regions 170a, 170b, and 170c each having a different thickness depending on an amount of laser irradiation. A surface of each of the first to third impurity regions 170a, 170b, and 170c may be an uneven surface or a flat surface.

Further, the impurity region 170 may have different impurity doping concentrations depending on the amount of the laser irradiation.

In a related art, a front surface and a back surface of a semiconductor substrate were simultaneously doped with impurities of first and second conductive types through a diffusion process, respectively to form a front surface field region and a back surface field region having the same thickness. Thus, a separate etching process for etching the front surface field region was added.

However, in the embodiment of the invention, because the impurity region 170 and the front surface field region 171 containing impurities of the second conductive type are simultaneously formed using the laser before the diffusion process, a separate etching process for forming the front surface field region 171 at a desired thickness is not necessary.

Next, as shown in FIG. 4K, impurities of the first dopant layer 180 and impurities of the second dopant layer 182 may be simultaneously diffused to form the plurality of emitter regions 121 and the plurality of back surface field regions 172.

More specifically, impurities of the second conductive type of the first dopant layer 180 may be diffused into the intrinsic semiconductor layer 160 in a diffusion furnace of about 850° C. through a thermal process to form the plurality of emitter regions 121. Further, impurities of the first conductive type of the second dopant layer 182 may be diffused into the first to third impurity regions 170a, 170b, and 170c in the diffusion furnace of about 850° C. through the thermal process to form the plurality of back surface field regions 172.

A portion of the intrinsic semiconductor layer 160, into which the impurities of the second conductive type are diffused, may be formed as the plurality of emitter regions 121, and a remaining portion except a portion of the first to third impurity regions 170a, 170b, and 170c, into which the impurities of the first conductive type are diffused, may be formed as the plurality of back surface field regions 172 (refer to FIG. 2). Namely, the plurality of emitter regions 121 may contain impurities of the second conductive type (for example, the p-type) opposite the first conductive type of the semiconductor substrate 110, and the plurality of back surface field regions 172 may be a region (for example, an n⁺-type region or an n⁺⁺-type region) which is more heavily doped than the semiconductor substrate 110 with impurities of the same conductive type as the n-type semiconductor substrate 110. The plurality of emitter regions 121 and the plurality of back surface field regions 172 may be alternately positioned.

In general, a diffusion speed of impurities of the first conductive type (for example, impurities of a group V element, such as phosphorus (P), arsenic (As), and antimony (Sb)) is slower than a diffusion speed of impurities of the second conductive type (for example, impurities of a group III element, such as boron (B), gallium (Ga), and indium (In)). Thus, after impurities of the first conductive type having the relatively slower diffusion speed are diffused to form the impurity region 170, impurities of the first and second conductive types may be simultaneously diffused through the thermal processing to form the emitter region 121 and the back surface field region 172 having the same thickness. Hence, the manufacturing process can be simplified, and the manufacturing cost may be reduced.

Next, an oxide (for example, boronsilicate glass (BSG)) containing boron (B), an oxide (for example, phosphorous silicate glass (PSG)) containing phosphorus (P), the first dopant layer 180, the second dopant layer 182, and the interlayer dielectric 112 may be sequentially removed. Hence, the emitter regions 121 and the back surface field regions 172 may be formed by doping n-type impurities and p-type impurities at a high concentration.

When the p-type impurities and the n-type impurities are diffused into the semiconductor substrate 110, the oxide BSG containing boron (B) and the oxide PSG containing phosphorus (P) may be produced. Therefore, the oxides BSG and PSG may be removed through the etching process. Hence, the oxides BSG and PSG, the first dopant layer 180, the second dopant layer 182, and the interlayer dielectric 112 may be removed. In this instance, the oxides BSG and PSG may be removed using hydrofluoric acid of about 10%.

Unlike the embodiment of the invention, the second dopant layer 182 containing impurities of the first conductive type may be formed by doping the semiconductor substrate 110 with impurities of a group V element, such as arsenic (As) and antimony (Sb), instead of phosphorus (P). Further, the first dopant layer 180 containing impurities of the second conductive type may be formed by doping the semiconductor substrate 110 with impurities of a group III element, such as gallium (Ga) and indium (In), instead of boron (B).

And at the same time, at least a portion of the intrinsic semiconductor layer 160 formed using the plurality of back surface field regions 172 may be crystallized.

In general, the semiconductor substrate 110 may have a crystallinity of 100 vol %. Hence, the back surface field region 172 formed through the laser irradiation may have a crystallinity of 40 vol % to 70 vol %, compared to the semiconductor substrate 110.

The first and third portions 1721 and 1723 of the back surface field region 172, which have the relatively high sheet resistance and the relatively low impurity doping concentration, may have a low crystallinity, and the second portion 1722 of the back surface field region 172, which has the relatively low sheet resistance and the relatively high impurity doping concentration, may have a high crystallinity.

More specifically, the first and third portions 1721 and 1723 may have the crystallinity equal to or less than 40 vol %, and the second portion 1722 may have the crystallinity greater than 40 vol %. In the embodiment of the invention, it may be preferable, but not required, that the second portion 1722 has the crystallinity of 70 vol % to 90 vol %. Thus, the crystallinity of 40 vol % to 90 vol % of the back surface field region 172 may be less than the crystallinity of 100 vol % of the semiconductor substrate 110.

In the embodiment of the invention, when the crystallinity of the first and third portions 1721 and 1723 is equal to or less than 40 vol %, sheet resistances of the first portion 1721 and the third portion 1723 may be 50 Ohm/sq at most and specific resistances of the first portion 1721 and the third portion 1723 may be 1.75×10⁻³ to 5.0×10⁻³ Ωcm. When the crystallinity of the second portion 1722 is greater than 40 vol %, a sheet resistance of the second portion 1722 may be 25 Ohm/sq at most and a specific resistance of the second portion 1722 may be 8.75×10⁻⁴ to 1.0×10⁻² Ωcm.

The crystallinity of the first portion 1721 may be greater or less than the crystallinity of the third portion 1723. Alternatively, the crystallinity of the first portion 1721 may be equal to the crystallinity of the third portion 1723.

When the crystallinity of the back surface field region 172 is equal to or greater than 90 vol %, a crystallizing process for crystallizing silicon has to be performed at a high temperature for several tens of hours.

Hence, when the back surface field region 172 has the crystallinity of about 40 vol % to 90 vol %, grain size of silicon increases. Hence, it may be easy to dope n-type impurities or p-type impurities.

Referring to FIG. 5, the back surface field region 172 may include the first to third portions 1721, 1722, and 1723 each having the different impurity doping concentration depending on an amount of the laser irradiation.

Namely, when the second portion 1722 having the relatively large amount of the laser irradiation has the sheet resistance of 25 Ohm/sq, the specific resistance of the second portion 1722 may be 8.75×10⁻⁴ to 1.0×10⁻² Ωcm. Further, when the first and third portions 1721 and 1723 having the relatively small amount of the laser irradiation have the sheet resistance of 50 Ohm/sq, the specific resistance of the first and third portions 1721 and 1723 may be 1.75×10⁻³ to 5.0×10⁻³ Ωcm.

More specifically, when the specific resistance of the second portion 1722 is equal to or less than 1.75×10⁻³ Ωcm, passivation characteristic of the second portion 1722 may be reduced because of the excessive doping of the second portion 1722. Hence, the efficiency of the solar cell may be reduced due to a reduction in an open-circuit voltage. Further, when the specific resistance of the second portion 1722 is equal to or greater than 5.0×10⁻³ Ωcm, a resistance of the back surface field region 172 may increase because of a lack of a doping amount. Hence, a contact resistance may increase, and the adhesive strength between the back surface field region 172 and the second electrode 142 may be reduced.

When the specific resistance of the first and third portions 1721 and 1723 is equal to or less than 8.75×10⁻⁴ Ωcm or equal to or greater than 1.0×10⁻² Ωcm, it may be difficult to produce and move carriers.

Unlike the back surface field region 172 described above, the first and third portions 1721 and 1723 may be doped at the high concentration, and the second portion 1722 may be doped at the low concentration by adjusting a frequency and an intensity of the laser. Alternatively, at least one of the first to third portions 1721, 1722, and 1723 may be doped at the high concentration or the low concentration. Hence, each of the first to third portions 1721, 1722, and 1723 may have a predetermined impurity doping concentration within the fixed range or have an impurity doping concentration which continuously or discontinuously changes within the fixed range.

Unlike the embodiment of the invention, the emitter region 121 and the back surface field region 172 may be crystallized depending on an irradiation location of the laser.

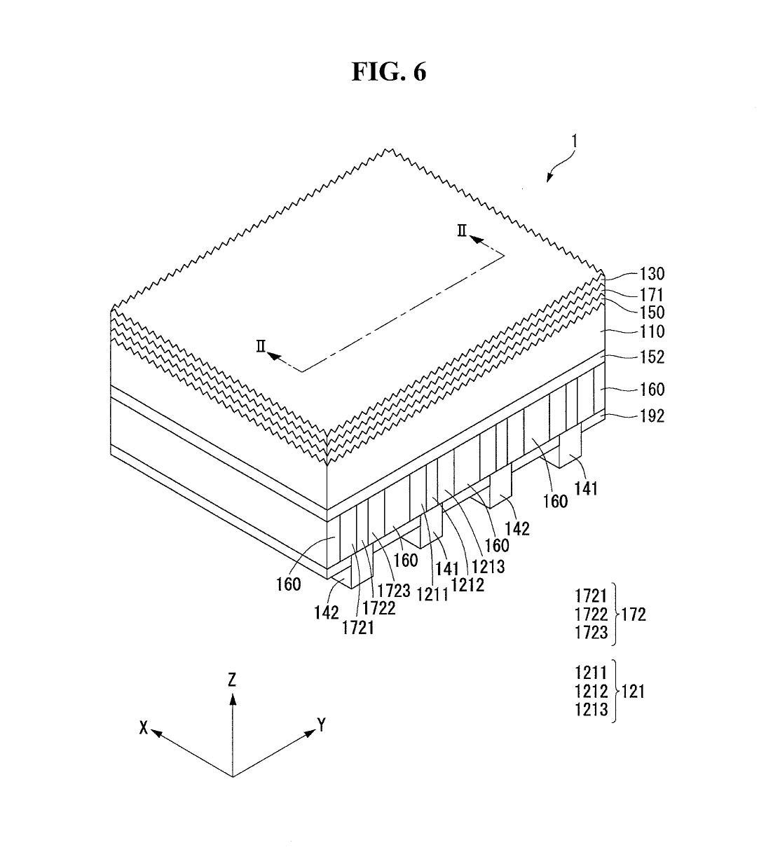

Each of the emitter region 121 and the back surface field region 172 may include first and second portions each having a different impurity doping concentration or first to third portions each having a different impurity doping concentration. For example, referring to FIG. 6, each of an emitter region 121 and a back surface field region 172 may include first to third portions each having a different impurity doping concentration. Namely, the emitter region 121 may include a second portion 1212 having a high impurity doping concentration and a first portion 1211 and a third portion 1213 each having a low impurity doping concentration lower than the impurity doping concentration of the second portion 1212. The back surface field region 172 may include a second portion 1722 having a high impurity doping concentration and a first portion 1721 and a third portion 1723 each having a low impurity doping concentration lower than the impurity doping concentration of the second portion 1722. In embodiments of the invention, the first electrode 141 may be on only the second portion 1212, or may be on one or more of the first, second and third portions 1211, 1212 and 1213. Also, the second electrode 142 may be on only the second portion 1722, or may be on one or more of the first, second and third portions 1721, 1722 and 1723.

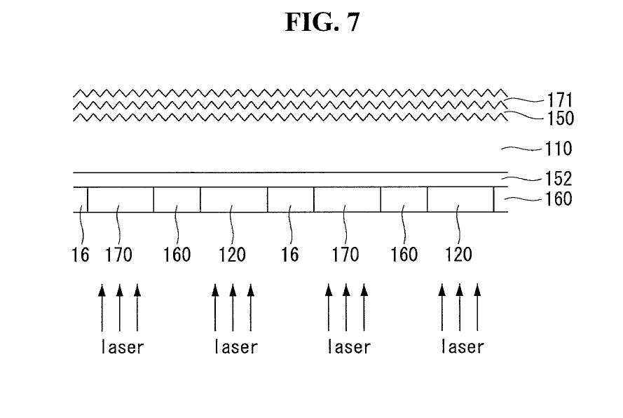

Referring to FIG. 7, the first to third portions 1211 to 1213 of the emitter region 121 may be formed by irradiating a laser onto a first impurity region 120 formed by diffusing a first dopant layer 180 containing impurities of a second conductive type. The first to third portions 1721 to 1723 of the back surface field region 172 may be formed by irradiating a laser onto a second impurity region 170 formed by diffusing a second dopant layer 182 containing impurities of a first conductive type. In this instance, the first to third portions 1211 to 1213 of the emitter region 121 and the first to third portions 1721 to 1723 of the back surface field region 172 may be simultaneously formed.

More specifically, the first and third portions 1211 and 1213 of the emitter region 121 and the first and third portions 1721 and 1723 of the back surface field region 172 may have a crystallinity equal to or less than 40 vol %, and the second portion 1212 of the emitter region 121 and the second portion 1722 of the back surface field region 172 may have a crystallinity greater than 40 vol %. In the embodiment of the invention, it may be preferable, but not required, that the second portion 1212 of the emitter region 121 and the second portion 1722 of the back surface field region 172 have the crystallinity of 70 vol % to 90 vol %. Thus, the crystallinity of 40 vol % to 90 vol % of the emitter region 121 and the back surface field region 172 may be less than a crystallinity of 100 vol % of a semiconductor substrate 110.

In the embodiment of the invention, when the crystallinity of the first and third portions 1211 and 1213 of the emitter region 121 is equal to or less than 40 vol %, sheet resistances of the first and third portions 1211 and 1213 may be 250 Ohm/sq at most and specific resistances of the first and third portions 1211 and 1213 may be 8.7×10⁻³ to 1.0×10⁻² Ωcm. When the crystallinity of the second portion 1212 of the emitter region 121 is greater than 40 vol %, a sheet resistance of the second portion 1212 may be 150 Ohm/sq at most and a specific resistance of the second portion 1212 may be 2.5×10⁻³ to 5.0×10⁻³ Ωcm. When the crystallinity of the first and third portions 1721 and 1723 of the back surface field region 172 is equal to or less than 40 vol %, sheet resistances of the first and third portions 1721 and 1723 may be 50 Ohm/sq at most and specific resistances of the first and third portions 1721 and 1723 may be 1.75×10⁻³ to 5.0×10⁻³ Ωcm. When the crystallinity of the second portion 1722 of the back surface field region 172 is greater than 40 vol %, a sheet resistance of the second portion 1722 may be 25 Ohm/sq at most and a specific resistance of the second portion 1722 may be 8.75×10 to 1.0×10⁻² Ωcm.

An anti-diffusion layer may be additionally formed between the plurality of emitter regions 121 and the plurality of back surface field regions 172, thereby preventing the diffusion of the plurality of emitter regions 121 and the plurality of back surface field regions 172.

Referring to FIG. 6, a passivation layer 192 may be additionally formed on a back surface of the semiconductor substrate 110. More specifically, the passivation layer 192 may be formed on back surfaces of the plurality of emitter regions 121 and back surfaces of the plurality of back surface field region 172. The passivation layer 192 may be formed of non-crystalline semiconductor. The passivation layer 192 may include a plurality of openings. The plurality of emitter regions 121 may be electrically and physically connected to first electrodes 141 through the plurality of openings, and the plurality of back surface field region 172 may be electrically and physically connected to second electrodes 142 through the plurality of openings.

For example, the passivation layer 192 may be formed of intrinsic hydrogenated amorphous silicon (i-a-Si:H). The passivation layer 192 may perform a passivation function, which converts a defect, for example, dangling bonds existing at and around the surface of the semiconductor substrate 110 into stable bonds using hydrogen (H) contained in the passivation layer 192 and prevents or reduces a recombination and/or a disappearance of carriers moving to the surface of the semiconductor substrate 110. Thus, the passivation layer 192 may reduce an amount of carriers lost by the defect at and around the surface of the semiconductor substrate 110. Hence, the passivation layer 192 positioned on the front surface and the back surface of the semiconductor substrate 110 may reduce an amount of carriers lost by the defect at and around the surface of the semiconductor substrate 110, thereby improving the efficiency of the solar cell 1.

Next, the plurality of first electrodes 141 may be formed on the plurality of emitter regions 121, and the plurality of second electrodes 142 may be formed on the plurality of back surface field region 172. Hence, the solar cell 1 may be completed (refer to FIG. 1).

More specifically, the plurality of first and second electrodes 141 and 142 may be formed by applying an electrode paste to the back surfaces of the plurality of emitter regions 121 and the back surfaces of the plurality of back surface field region 172 using a screen printing method and then firing the electrode paste. Alternatively, the plurality of first and second electrodes 141 and 142 may be formed using a plating method, a sputtering method, an electron beam deposition method, a PECVD method, a CVD method, etc.

Next, silicon nitride may be deposited on a front surface field region 171 to form an anti-reflection layer 130. In this instance, the anti-reflection layer 130 may be formed on an entire front surface of the front surface field region 171.

The anti-reflection layer 130 may be formed using the PECVD method or the sputtering method, etc.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a crystalline semiconductor substrate containing impurities of a first conductive type;
a tunnel layer positioned on the crystalline semiconductor substrate;
a semiconductor layer formed on the tunnel layer, the semiconductor layer having a crystallinity less than a crystallinity of the crystalline semiconductor substrate, the semiconductor layer including a first doped region of a second conductive type opposite the first conductive type and a second doped region containing impurities of the first conductive type at a higher concentration than that of the crystalline semiconductor substrate;
a first electrode connected to the first doped region; and
a second electrode connected to the second doped region,
wherein at least one of the first doped region or the second doped region includes a first portion having a first specific resistance and a second portion having a second specific resistance, the first specific resistance being larger than the second specific resistance.

2. The solar cell of claim 1, wherein the first portion has a first impurity doping concentration, and the second portion has a second impurity doping concentration higher than the first impurity doping concentration.

3. The solar cell of claim 1, wherein the first specific resistance of the first portion is 8.75×10⁻⁴ to 1.0×10⁻² Ωcm, and the second specific resistance of the second portion is 1.75×10⁻³ to 5.0×10⁻³ Ωcm.

4. The solar cell of claim 1, wherein the first specific resistance of the first portion is 8.7×10⁻³ to 1.0×10⁻² Ωcm, and the second specific resistance of the second portion is 2.5×10⁻³ to 5.0×10⁻³ Ωcm.

5. The solar cell of claim 1, wherein a crystallinity of the first portion is less than a crystallinity of the second portion.

6. The solar cell of claim 5, wherein the crystallinity of the first portion is equal to or less than about 40 vol %, and the crystallinity of the second portion exceeds about 40 vol %.

7. The solar cell of claim 6, wherein the crystallinity of the second portion is about 70 vol % to about 90 vol %.

8. The solar cell of claim 1, wherein the first portion is in the plural, and the second portion is positioned between the plurality of first portions, and
wherein the second portion is positioned on the first electrode or the second electrode.

9. The solar cell of claim 1, wherein the first and second portions each have a dot shape, and the second portion is positioned inside the first portion.

10. The solar cell of claim 1, further comprising a third doped region on a front surface of the crystalline semiconductor substrate.

11. The solar cell of claim 10, further comprising an intrinsic semiconductor layer formed between the first doped region and the second doped region and positioned on the tunnel layer, on which the first doped region and the second doped region are not formed.

12. The solar cell of claim 1, wherein the semiconductor layer is an amorphous silicon layer or a polycrystalline silicon layer.

13. A method for manufacturing a solar cell, the method comprising:
preparing a crystalline semiconductor substrate containing impurities of a first conductive type;
forming a tunnel layer on the crystalline semiconductor substrate;
forming an intrinsic semiconductor layer on the tunnel layer;
diffusing impurities of a second conductive type opposite the first conductive type into the intrinsic semiconductor layer to form a first doped region having a crystallinity less than a crystallinity of the crystalline semiconductor substrate; and
diffusing impurities of the first conductive type into the intrinsic semiconductor layer to form a second doped region having a crystallinity less than the crystallinity of the crystalline semiconductor substrate,
wherein the forming of the first doped region or the second doped region includes forming an impurity layer containing impurities of the second conductive type or impurities of the first conductive type at the intrinsic semiconductor layer, irradiating a laser onto the impurity layer, and diffusing the impurity layer.

14. The method of claim 13, wherein the diffused impurity layer forms the first doped region or the second doped region through thermal processing.

15. The method of claim 13, wherein the crystallinity of the first doped region or the second doped region is about 40 vol % to about 90 vol %.

16. The method of claim 13, wherein at least one of the first doped region or the second doped region includes a first portion and a second portion each having a different specific resistance depending on an amount of laser irradiation.

17. The method of claim 13, wherein at least one of the first doped region or the second doped region includes a first portion and a second portion each having a different crystallinity depending on an amount of laser irradiation.

18. The method of claim 13, wherein the first doped region and the second doped region are simultaneously formed.

19. A method for manufacturing a solar cell, the method comprising:
doping a second impurity layer of a second conductive type opposite a first conductive type on a back surface of a semiconductor substrate containing impurities of the first conductive type to form a first doped region;
doping a first impurity layer containing impurities of the first conductive type on the back surface of the semiconductor substrate to form a second doped region; and
additionally doping the first impurity layer or the second impurity layer on the first doped region or the second doped region to form a first portion or a second portion each having a different impurity doping concentration,
wherein an impurity doping concentration of the first portion is lower than an impurity doping concentration of the second portion.

20. The method of claim 19, wherein the first portion or the second portion is formed through laser irradiation.
